(19) United States
(12) Patent Application Publication
(10) Pub. No.: US 2022/0285385 A1
(43) Pub. Date: Sep. 8, 2022

(54) MEMORY DEVICE AND METHOD FOR FABRICATING THE SAME

(71) Applicant: MACRONIX INTERNATIONAL CO., LTD., Hsinchu (TW)

(72) Inventor: Erh-Kun LAI, Taichung City (TW)

(21) Appl. No.: 17/190,576

(22) Filed: Mar. 3, 2021

(51) Int. Cl. H01L 27/11582; H01L 29/06; H01L 21/764

(52) U.S. Cl. CPC H01L 27/11582; H01L 29/0649; H01L 21/764

(57) ABSTRACT

A memory device and a method for fabricating the memory device are provided. The memory device includes a substrate having an upper surface; a stack disposed on the substrate, wherein the stack includes a first insulating layer, a first conductive layer, a second insulating layer, a second conductive layer, and a third insulating layer sequentially stacked on the upper surface of the substrate along a first direction; a channel layer penetrating the stack along the first direction, wherein the channel layer has a ring shape along a cross section view in a plane perpendicular to the first direction; and a memory layer disposed between the channel layer and the second conductive layer.

### BACKGROUND OF THE INVENTION

### Field of the Invention

The invention relates in general to a semiconductor device and a method for fabricating the same, and more particularly to a memory device and a method for fabricating the same.

### Description of the Related Art

Generally speaking, flash memory devices can be classified into NOR or NAND flash memory devices. Among them, the NOR memory device typically provides faster programming and reading speed by connecting one end of each of memory cells to the ground and the other end of each of memory cells to the bit line. In some embodiments, the NAND or NOR flash memory system is a two-dimensional type, and the memory cells exist in a two-dimensional array of a substrate. However, with more and more applications nowadays, the size limit of the two-dimensional structure is no longer sufficient. Therefore, in order to provide a memory device with a higher storage capacity, there is still an urgent need to develop a three-dimensional memory device with good electrical characteristics (for example, good data storage reliability and operating speed).

### SUMMARY OF THE INVENTION

In the present disclosure, a memory device and a method for fabricating the same are provided to solve at least part of the above-mentioned problems.

According to an embodiment, a memory device is provided. The memory device includes a substrate having an upper surface; a stack disposed on the substrate, wherein the stack includes a first insulating layer, a first conductive layer, a second insulating layer, a second conductive layer, and a third insulating layer sequentially stacked on the upper surface of the substrate along a first direction; a channel layer penetrating the stack along the first direction, wherein the channel layer has a ring shape in a top view; and a memory layer disposed between the channel layer and the second conductive layer.

According to another embodiment, a method for fabricating the memory device is provided. The method includes the following steps. Firstly, a substrate is provided, wherein the substrate has an upper surface. Next, a laminated body is formed on the substrate. The laminated body includes a first insulating layer, a first conductive layer, a second insulating layer, a sacrificial layer, and a third insulating layer sequentially stacked on the upper surface of the substrate along a first direction. A first opening is formed, and the first opening penetrates the laminated body. A channel layer is formed in the first opening, wherein the channel layer has a ring shape in a top view. The sacrificial layer is removed. A second conductive layer is formed at a position where the sacrificial layer is removed. After that, a memory layer is formed between the channel layer and the second conductive layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 to FIG. 18A are cross-sectional views of a method for fabricating a memory device according to an embodiment of the present disclosure.

FIG. 18B is a partial top view of the memory device corresponding to the connecting line A-A′ of FIG. 18A.

FIGS. 19 to 36A are cross-sectional views of a method for fabricating a memory device according to another embodiment of the present disclosure.

FIG. 36B is a partial top view of the memory device corresponding to the connecting line B-B′ of FIG. 36A.

FIG. 36C show a cross-sectional view of a memory device according to a further embodiment of the present disclosure.

FIG. 37 to FIG. 38 are cross-sectional views of a method for fabricating a memory device according to a further embodiment of the disclosure.

### DETAILED DESCRIPTION OF THE INVENTION

In the following detailed description, for ease of explanation, various specific details are provided to understand the embodiments of the present disclosure as a whole. However, it should be understood that one or more embodiments can be implemented without employing these specific details. In other cases, in order to simplify the drawings, the known structures and components are shown in schematic diagrams.

The memory device and a method for fabricating the same will be described below. For ease of explanation, the following embodiments will specifically take a 3D NOR memory device as an example. However, the present invention is not limited thereto. Compared with the two-dimensional NOR memory device, the three-dimensional NOR memory device of the present application has a higher storage capacity and can reduce the required area of the device.

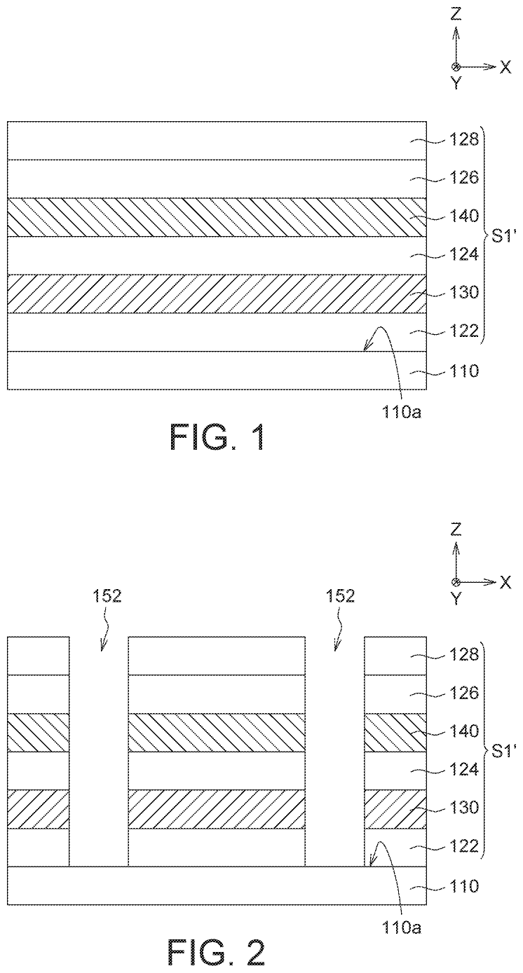

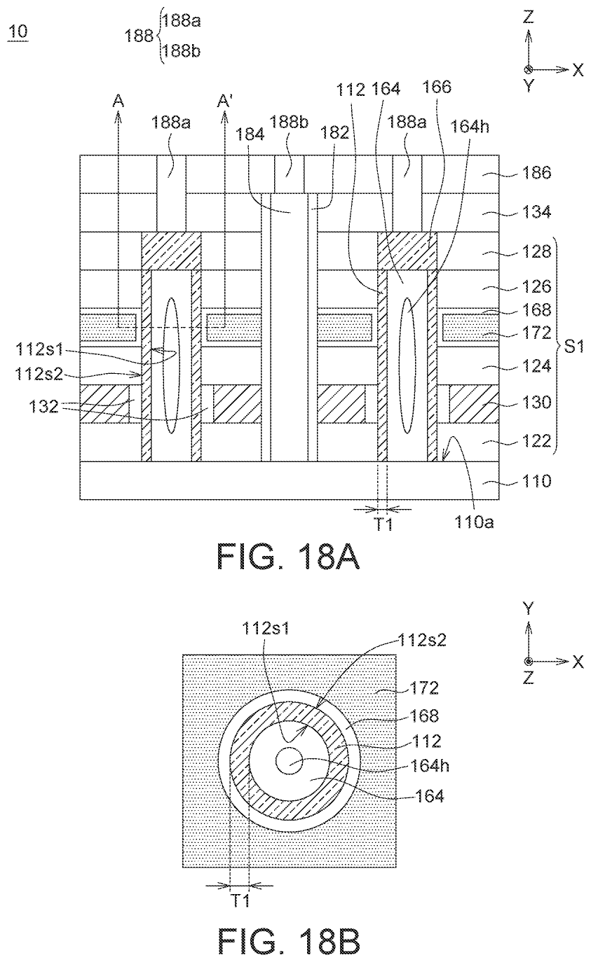

FIGS. 1 to 18A show cross-sectional views of a method for fabricating a memory device 10 according to an embodiment of the present disclosure, for example, corresponding to a plane formed by a first direction (such as Z-axis direction) and a second direction (such as X-axis direction); FIG. 18B shows a partial top view of the memory device 10 corresponding to the connecting line A-A′ of FIG. 18A, for example corresponding to a plane formed by the second direction (such as X-axis direction) and a third direction (for example, Y-axis direction). The first direction, the second direction, and the third direction are intersected with each other, for example, perpendicular to each other, but the present invention is not limited thereto.

Referring to FIG. 1, a substrate 110 is provided, and a laminated body S1′ is formed on the upper surface 110a of the substrate 110. The laminated body S1′ includes a first insulating layer 122, a first conductive layer 130, a second insulating layer 124, a sacrificial layer 140, a third insulating layer 126, and a fourth insulating layer 128 sequentially stacked on the upper surface 110a of the substrate 110 along the first direction, for example, by a deposition process.

In some embodiments, the substrate 110 may be a silicon substrate or other suitable substrate, which may be doped with P-type dopants. The first insulating layer 122, the second insulating layer 124, the third insulating layer 126, and the fourth insulating layer 128 may be formed of oxide, such as silicon dioxide. The first conductive layer 130 may be formed of a conductive material, such as tungsten (W), aluminum (Al), titanium nitride (TiN), tantalum nitride (TaN), doped or undoped polysilicon or other suitable materials. In some embodiments, the first conductive layer 130 may be an n-type doped polysilicon layer. The sacrificial layer 140 may be formed of silicon nitride (SiN).

Referring to FIG. 2, a plurality of first openings 152 are formed. Each of the first openings 152 penetrates the laminated body S1′ and exposes a portion of the substrate 110, but the present invention is not limited thereto. In some embodiments, the first openings 152 may be formed by an etching process, such as a dry etching process. In some embodiments, the substrate 110 may be overetched so that the bottom of the first opening 152 is lower than the upper surface 110a of the substrate 110.

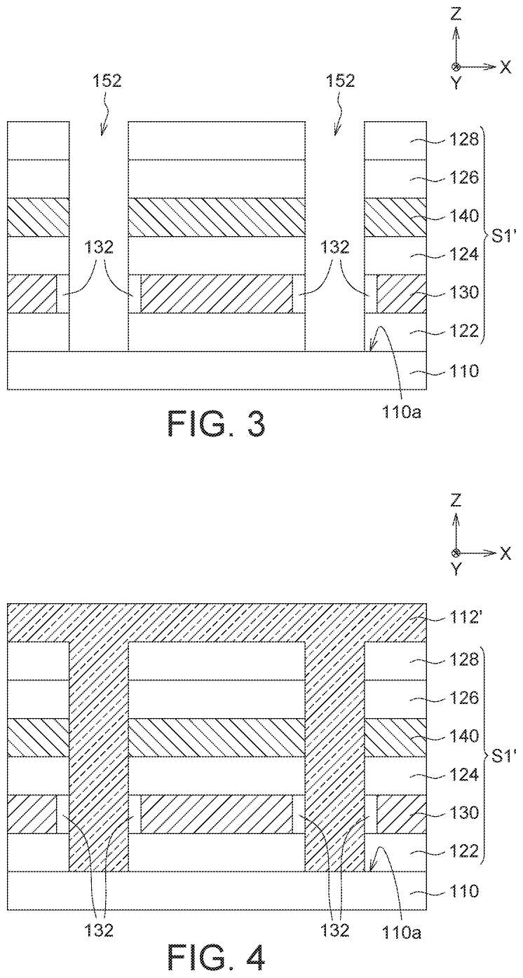

Referring to FIG. 3, an oxide layer 132 is formed on a side surface of the first conductive layer 130 exposed from the first opening 152 by an oxidation process, and an oxide layer (not shown) is formed on the surface of the substrate 110 exposed from the first opening 152. In some embodiments, the first conductive layer 130 is an n-type doped polysilicon layer, and the substrate 110 is a silicon substrate; after an oxidation process and high temperature, the oxide layer 132 including silicon dioxide is formed on the side surface of the first conductive layer 130 exposed from the first opening 152; an oxide layer (not shown) including silicon dioxide is formed on the surface of the substrate 110 exposed from the first opening 152. Thereafter, the oxide layer formed on the surface of the substrate 110 is removed by an etching process, and the oxide layer 132 is remained. That is, if the substrate 110 is a silicon substrate, it will also be oxidized. The etching process may be a reactive ion etching (RIE), but the present invention is not limited thereto. In some embodiments, the etching process may remove a small portion of the oxide layer 132.

Referring to FIG. 4, an epitaxial growth layer 112′ covering the oxide layer 132, the first openings 152, and the fourth insulating layer 128 is formed by an epitaxial growth process. The epitaxial growth layer 112′ is, for example, an epitaxial growth layer of silicon.

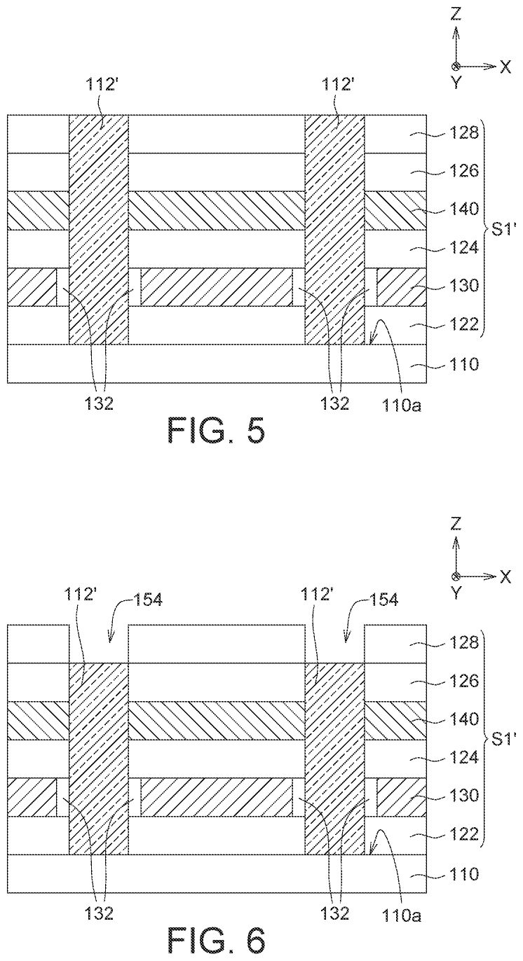

Referring to FIG. 5, the epitaxial growth layer 112′ disposed outside the first opening 152 is removed by a planarization process. The planarization process is, for example, a Chemical-Mechanical Planarization (CMP) process.

Referring to FIG. 6, a portion of the epitaxial growth layer 112′ is removed by an etching process to form a plurality of second openings 154 extending along the first direction. That is, each of the second openings 154 is formed between the fourth insulating layer 128 and a remaining portion of the epitaxial growth layer 112′. A bottom surface of each of the second openings 154 is, for example, higher than a top surface of the sacrificial layer 140. In the present embodiment, the top surface of the epitaxial growth layer 112′ disposed under the second opening 154 is coplanar with a top surface of the third insulating layer 126, but the invention is not limited thereto. In some of other embodiments, the top surface of the epitaxial growth layer 112′ is located at the height ranging within the third insulating layer 126 and the fourth insulating layer 128.

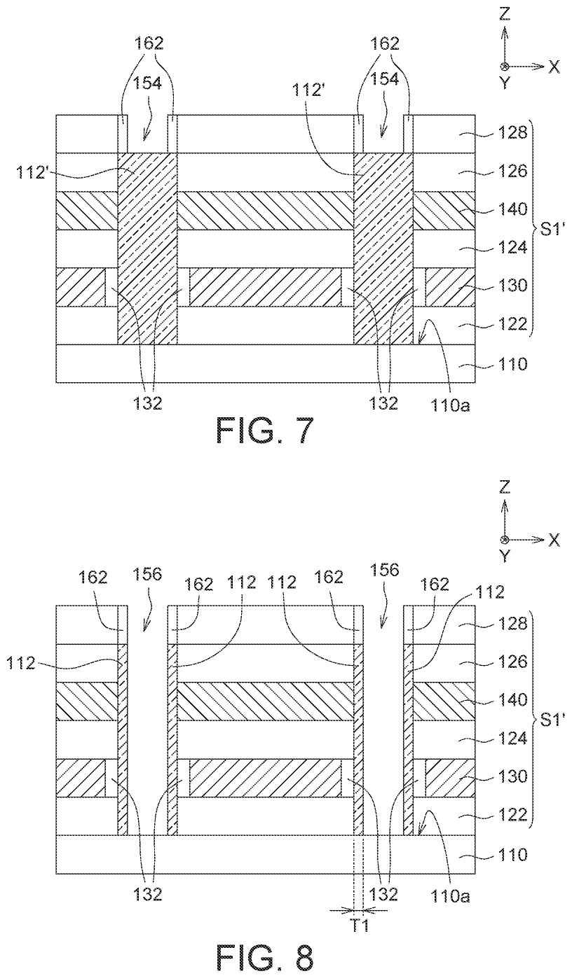

Referring to FIG. 7, an insulating material is filled in the second openings 154 by a deposition process. The insulating material may be oxide or nitride. After that, a portion of the insulating material is removed by an etching process to form a spacer 162 disposed on a sidewall of the second opening 154. The material of the spacer 162 may be oxide, nitride, SiON, BN or TiN or TaN. The spacer 162 can be dielectric or conductor spacer. Dielectric spacer is preferred. When the material of the spacer 162 is oxide, the purity of the oxide of the spacer 162 formed by the deposition method is less than the purity of the oxide of the oxide layer 132 formed by the oxidation process.

Referring to FIG. 8, a plurality of third openings 156 are formed by an etching process, and the third openings 156 penetrate a portion of the epitaxial growth layer 112′, the epitaxial growth layers 112′ disposed on the sidewalls of the first openings 152 are remained and the substrate 110 is exposed. That is, the epitaxial growth layer 112′ that is not protected by the spacer 162 is removed to form the third openings 256, and the channel layer 112 having a ring shape is formed in the first opening 152 (as shown in the top view of FIG. 18B). Optionally, if the thickness T1 of the channel layer 112 is to be reduced, an oxidation process may be used to form an oxide on the surface of the channel layer 112. Or, an iso-tropical silicon etching may be used to thin down the channel layer 112. In some embodiments, the thickness T1 of the channel layer 112 may be between 20 Å and 500 Å. In the prefer embodiment, the thickness T1 of the channel layer 112 may be between 20 Å to 200 Å. Compared with the comparative example where the channel layer is solid or columnar in the top view, the channel layer 112 in the present application has a ring shape in the top view and has a thinner thickness T1, which allows the gate (for example, a memory gate and a control gate, described below) has better control ability.

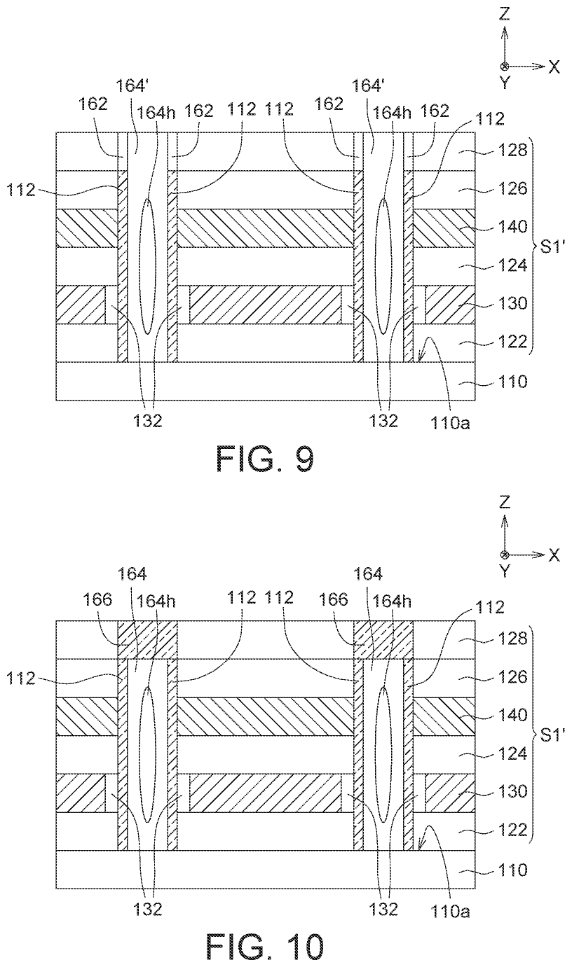

Referring to FIG. 9, the third openings 156 are filled with a dielectric material 164′ (such as silicon dioxide, silicon nitride or other suitable dielectric materials) after the channel layer 112 is formed, and an air gap 164h is formed in the third opening 156. In other embodiments, the dielectric material 164′ may not have an air gap 164h.

Hereafter, referring to FIG. 10, after the spacer 162 and the dielectric material 164′ adjacent to the spacer 162 are etched back, the remaining portion of the dielectric material 164′ forms a dielectric pillar 164. It is acceptable for spacer 162 to be etched or not etched. Then, the landing pad 166 is formed on the dielectric pillar 164, and the landing pad 166 has an electrical contact with the channel layer 112. The material of the landing pad 166 is, for example, N⁺ polysilicon or N⁺ polysilicon/salicide. In some embodiments, the spacer 162 may not be etched, and is remained after the landing pad 166 formation. In the present embodiment, the landing pad 166 contacts a top surface of the channel layer 112, but the contact position of the landing pad 166 of the present invention is not limited thereto, once the landing pad 166 is disposed above the sacrificial layer 140 and contacts the channel layer 112, it falls in the scope of the present invention, for example, the landing pad 166 may contact a portion of a side surface of the channel layer 112.

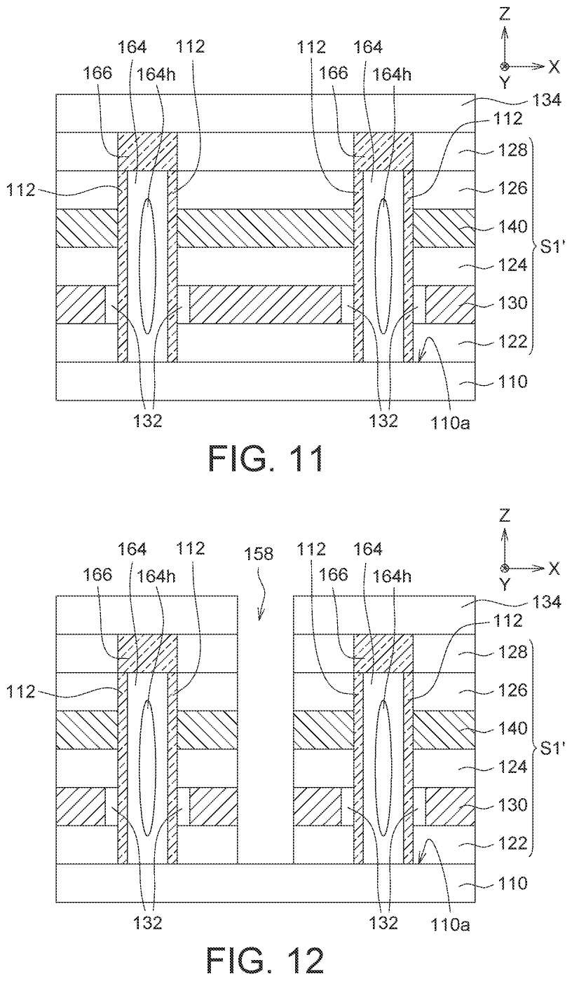

Referring to FIG. 11, after the landing pad 166 is formed, a capping layer 134 is formed to cover the laminated body S1′ and the landing pad 166. In one of the embodiments of the present invention, the capping layer 134 includes oxide.

Referring to FIG. 12, a trench 158 penetrating the laminated body S1′ is formed by an etching process, and a portion of the substrate 110 may be exposed by the trench 158.

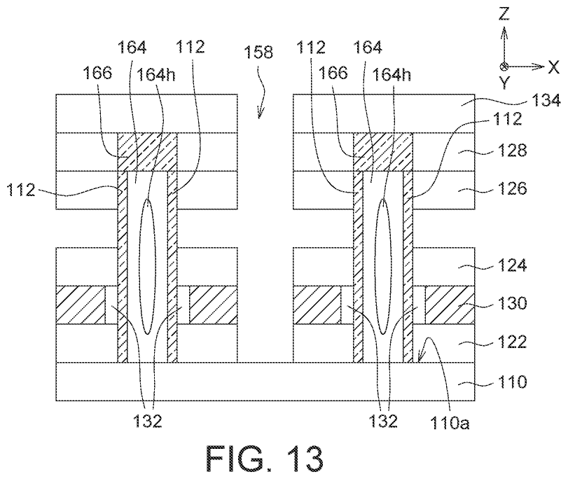

Thereafter, referring to FIG. 13, the sacrificial layer 140 is removed. In the present embodiment, a phosphoric acid (H₃PO₄) solution is used to remove the sacrificial layer 140 through the trench 158.

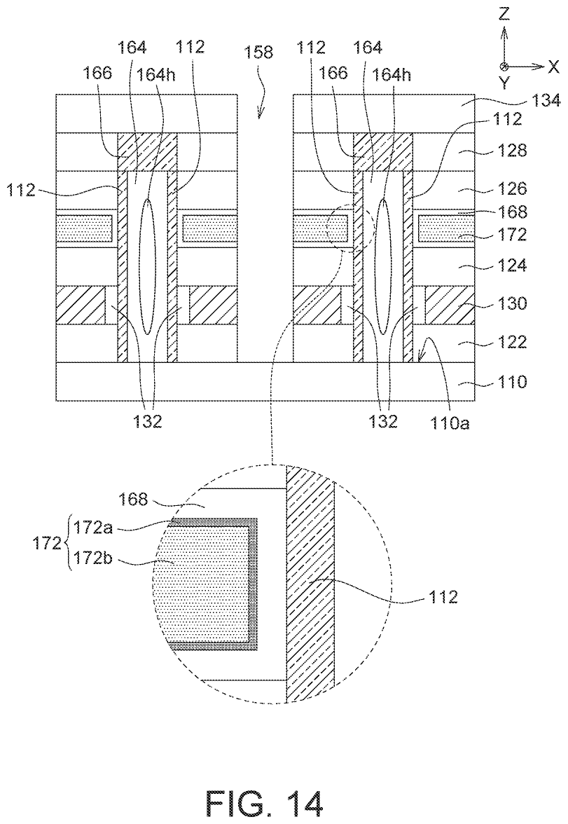

Next, referring to FIG. 14, a memory layer 168 and a second conductive layer 172 are sequentially formed at positions where the sacrificial layer 140 is removed. The memory layer 168 and the second conductive layer 172 can be respectively formed by a deposition process. A portion of the memory layer 168 extends along the first direction and is disposed between the second conductive layer 172 and the channel layer 112; the other portions of the memory layer 168 extend along the second direction and are disposed between the second conductive layer 172 and the second insulating layer 124, and disposed between the second conductive layer 172 and the third insulating layer 126. The memory layer 168 may be an oxide-hafnium oxide-oxide (Oₓ/HfOₓ doped with DM/Oₓ) memory layer, an oxide-nitride-oxide (ONO) memory layer, an oxide-nitrogen-oxide-nitride-oxide (ONONO) memory layer, oxide-nitride-oxide-nitride-oxide-nitride-oxide (ONONONO) memory layer or other suitable memory layers. Among them, the material DM can be silicon (Si), zirconia (ZrOₓ), aluminum (Al), yttrium (Y), cadmium (Cd), lanthanum (La) or other materials having a memory window and non-volatile memory (NVM) properties.

The second conductive layer 172 may be a multilayer structure. For example, the second conductive layer 172 includes a first conductive structure 172a and a second conductive structure 172b, and the first conductive structure 172a is disposed between the memory layer 168 and the second conductive structure 172b. For example, the material of the first conductive structure 172a may include titanium nitride (TiN) or Tantalum Nitride (TaN), and the material of the second conductive structure 172b may include tungsten (W), but the present invention is not limited thereto. Thereafter, the excessive portions of the memory layer 168 and the second conductive layer 172 are removed by an etching back process to expose the trench 158. Concaves created in the etching process or the etching back process can be filled by depositing oxide, and then the excessive oxide is removed by an etching process.

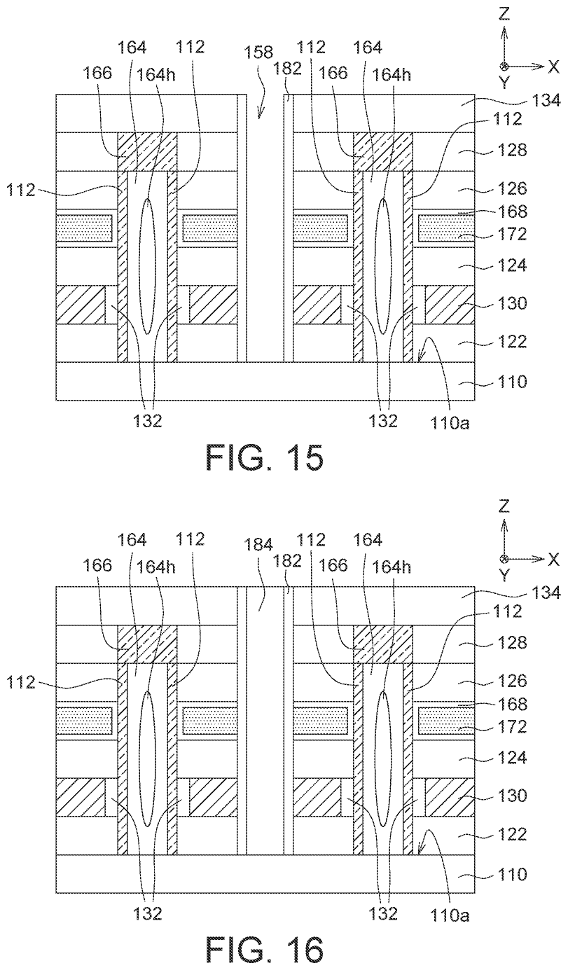

Next, referring to FIG. 15, after filling the trench 158 with an insulating material (for example, oxide), a portion of the insulating material is removed to expose a portion of the trench 158 and a portion of the substrate 110, and an isolation structure 182 is formed in the trench 158. The isolation structure 182 is formed, for example, by a deposition process, and the material of the isolation structure 182 may include oxide.

Referring to FIG. 16, the trench 158 is filled with the conductive material. Then, the excessive portion of the conductive material can be removed by a planarization process (such as a chemical mechanical planarization process) to form a conductive pillar 184 electrically in contact with the substrate 110. The isolation structure 182 surrounds the conductive pillar 184. The conductive pillar 184 may have a multilayer structure, such as a double-layer structure. For example, the material of the outer layer of the conductive pillar 184 may include titanium nitride (TiN), and the material of the inner layer of the conductive pillar 184 may include tungsten (W), but the present invention is not limited thereto. In an embodiment, the conductive pillar 184 may serve as a source line.

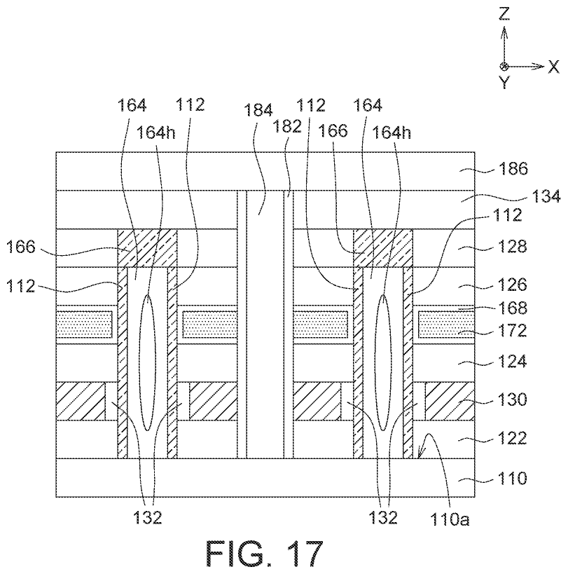

Referring to FIG. 17, a dielectric filling layer 186 is formed on the capping layer 134, the isolation structure 182 and the conductive pillar 184. The material of the dielectric filling layer 186 may include oxide.

After that, referring to FIG. 18A, a contact plug 188 that electrically contacts the landing pad 166 and the conductive pillar 184 is formed. The contact plug 188 includes a first plug 188a and a second plug 188b. The first plug 188a penetrates a portion of the dielectric filling layer 186 and the capping layer 134 to electrically contact the landing pad 166, and the second plug 188b penetrates a portion of the dielectric filling layer 186 to electrically contact the conductive pillar 184. The material of the contact plug 188 includes a conductive material, such as tungsten or other suitable conductive materials.

According to the above manufacturing steps, the present disclosure provides a memory device 10, as shown in FIGS. 18A and 18B. The memory device 10 includes a substrate 110, a stack S1, a capping layer 134, a dielectric filling layer 186, oxide layers 132, a memory layer 168, channel layers 112, a dielectric pillar 164, landing pads 166, an isolation structure 182, a conductive pillar 184, and contact plugs 188. The stack S1 is disposed on the upper surface 110a of the substrate 110, and the capping layer 134 and the dielectric filling layer 186 are sequentially disposed on the stack S1. The stack S1 includes a first insulating layer 122, a first conductive layer 130, a second insulating layer 124, a second conductive layer 172, a third insulating layer 126 and a fourth insulating layer 128 sequentially stacked on the upper surface 110a of the substrate 110 along the first direction.

In some embodiments, the substrate 110 may be a silicon substrate or other suitable substrate, which may be doped with P-type dopants. The first insulating layer 122, the second insulating layer 124, the third insulating layer 126, and the fourth insulating layer 128 may be formed of oxide, such as silicon dioxide. The first conductive layer 130 may be formed of a conductive material, such as tungsten (W), aluminum (Al), titanium nitride (TiN), tantalum nitride (TaN), doped or undoped poly-silicon or other suitable materials. In some embodiments, the first conductive layer 130 may be an n-type doped poly-silicon layer.

In the present embodiment, the second conductive layer 172 may have a multilayer structure, as shown in the enlarged view of FIG. 14. The second conductive layer 172 includes a first conductive structure 172a and a second conductive structure 172b, and the first conductive structure 172a is disposed between the memory layer 168 and the second conductive structure 172b. For example, the material of the first conductive structure 172a may include titanium nitride (TiN), or Tantalum Nitride (TaN), and the material of the second conductive structure 172b may include tungsten (W), but the present invention is not limited thereto.

As shown in FIG. 18A, the channel layer 112 and the dielectric pillar 164 penetrate a portion of the stack S1 along the first direction, that is, penetrate a portion of the first insulating layer 122, the first conductive layer 130, and the second insulating layer 124, the second conductive layer 172 and the third insulating layer 126. The channel layer 112 surrounds the dielectric pillar 164 and is disposed between the dielectric pillar 164 and the memory layer 168. The dielectric pillar 164 may have an air gap 164h. The landing pad 166 may be disposed on the dielectric pillar 164 and the channel layer 112, and the landing pad 166 may be in electrical contact with the channel layer 112. The oxide layer 132 may surround a portion of the channel layer 112. For example, the oxide layer 132 is disposed between the first conductive layer 130 and the channel layer 112. The oxide layer 132 is, for example, an oxide formed by directly performing an oxidation process on the first conductive layer 130. The channel layer 112 may be an epitaxial growth layer, for example, an epitaxial growth layer of silicon. In the top view shown in FIG. 18B (i.e. along a cross section view in the plane perpendicular to the first direction), the channel layer 112 has as ring shape and has an inner surface 112s1 and an outer surface 112s2. The inner surface 112s1 is opposite to the outer surface 112s2. The inner surface 112s1 may contact the dielectric pillar 164; the outer surface 112s2 may contact the first insulating layer 122, the oxide layer 132, the second insulating layer 124, the memory layer 168, and the third insulating layer 126. The thickness T1 of the channel layer 112 is defined as the average thickness between the inner surface 112s1 and the outer surface 112s2. In some embodiments, the thickness T1 of the channel layer 112 may be between 20 Å and 500 Å. In the prefer embodiment, the thickness T1 of the channel layer 112 may be between 20 Å to 200 Å. In the present embodiment, the ring shape of the channel layer 112 may be a circle, but the present invention is not limited thereto, the ring shape of the channel layer 112 may be an ellipse, a polygon or the other suitable shape.

Compared with the comparative example where the channel layer is solid or columnar in the top view (the size of the first opening used to form the channel layer being the same as the size of the first opening 152 of the present application), the channel layer 112 of the present application has a ring shape in the top view (for example, FIG. 18B) and has a thinner thickness T1, such that the Subthreshold Swing (SS) may be decreased, and the random telegraph noise may be reduced; the programming/erasing window (P/E window) can be larger. That is, the gate may have a better control ability, and it is more advantageous for operating the memory, for example, the memory having a multi-level storage unit (Multi-Level Cell, MLC) or Triple-Level Cell (TLC).

In the present embodiment, a portion of the memory layer 168 extends along the first direction and is disposed between the second conductive layer 172 and the channel layer 112; other portions of the memory layer 168 extend along the second direction and are disposed between the second conductive layer 172 and the second insulating layer 124, and between the second conductive layer 172 and the third insulating layer 126, the present invention is not limited thereto. The memory layer 168 may be an oxide-hafnium oxide doped with material DM-oxide (Oₓ/HfOₓ doped with material DM/Oₓ) memory layer, an oxide-nitride-oxide (ONO) memory layer, an oxide-nitride-oxide-nitride-oxide (ONONO) memory layer, an oxide-nitride-oxide-nitride-oxide-nitride-oxide (ONONONO) memory layer or other suitable memory layers. Among them, the material DM can be silicon (Si), Zirconium oxide (ZrOₓ), aluminum (Al), yttrium (Y), cadmium (Cd), lanthanum (La) or other materials having the memory windows and non-volatile memory (NVM) properties.

According to an embodiment, the isolation structure 182 and the conductive pillar 184 penetrate the capping layer 134 and the stack S1 along the first direction, and the isolation structure 182 surrounds the conductive pillar 184. The contact plugs 188 are in electrical contact with the landing pads 166 and the conductive pillar 184. The contact plugs 188 include first plugs 188a and a second plug 188b. The first plugs 188a penetrate a portion of the dielectric filling layer 186 and the capping layer 134 to electrically contact the landing pad 166. The second plug 188b penetrates a portion of the dielectric filling layer 186 to electrically contact the conductive pillar 184. The material of the contact plugs 188 includes a conductive material, such as tungsten or other suitable conductive materials.

In some embodiments, the conductive pillar 184 can be used as a source line; the first conductive layer 130 can be used as a control gate; and the second conductive layer 172 can be used as a memory gate.

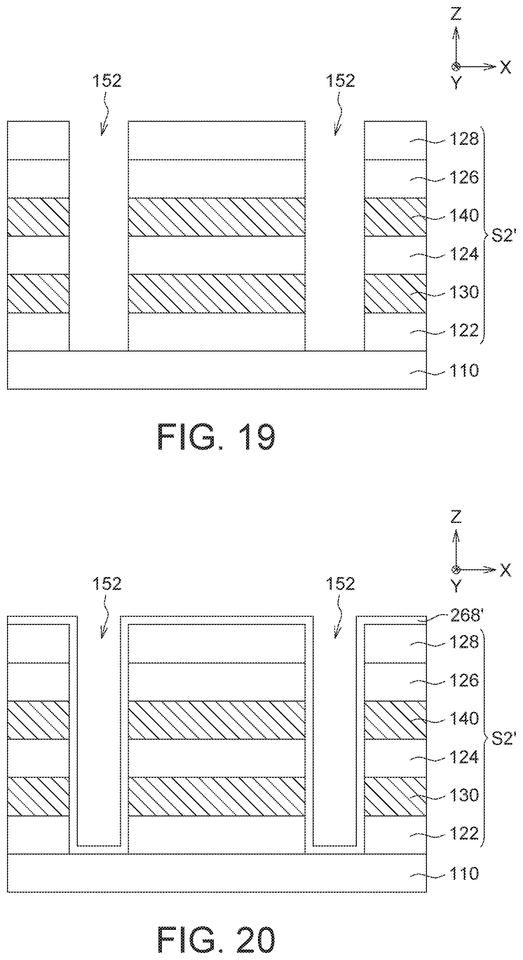

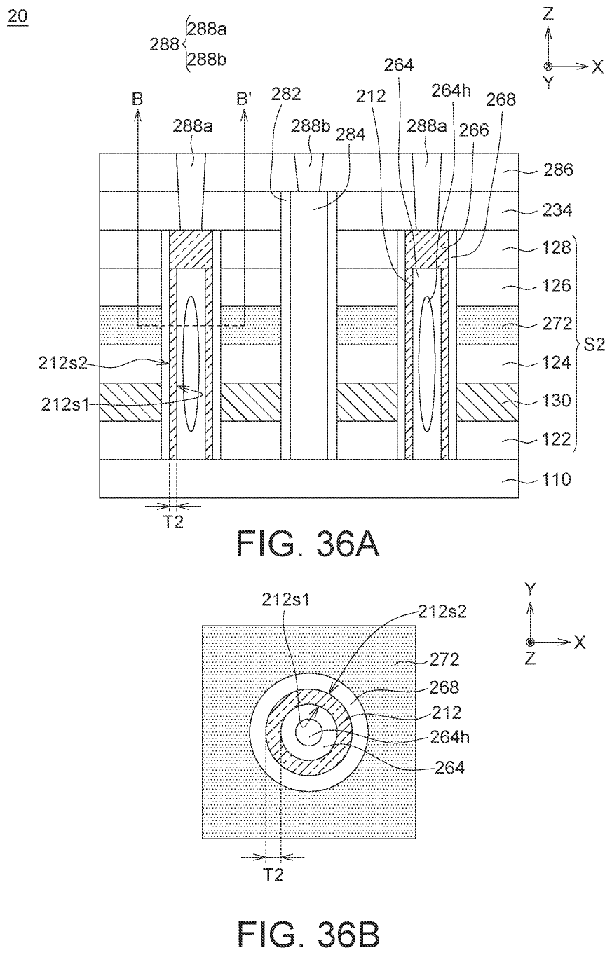

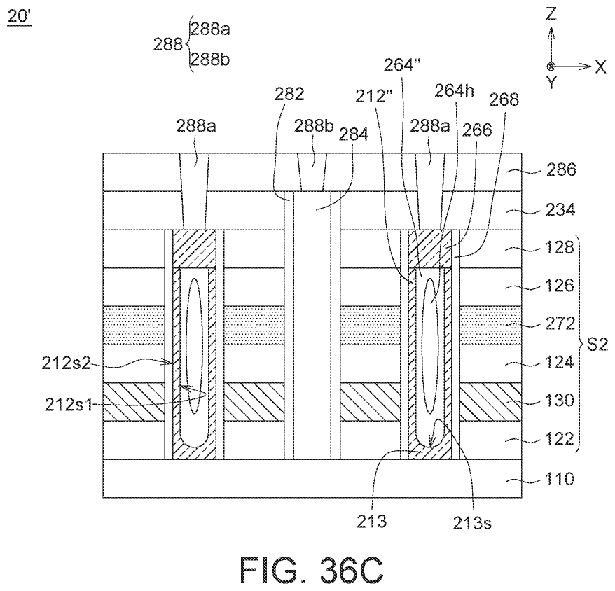

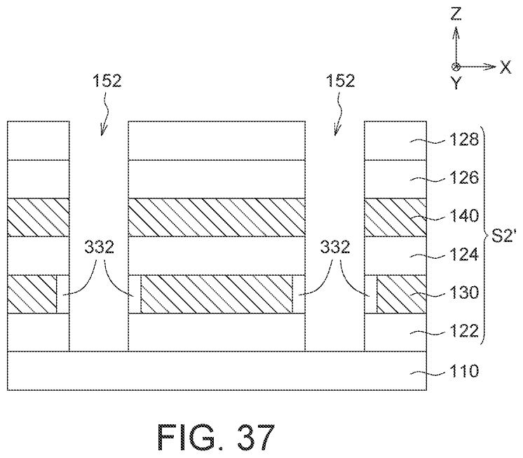

FIGS. 19 to 36A show cross-sectional views of a method for fabricating a memory device 20 according to another embodiment of the present disclosure, for example, corresponding to a plane formed by the first direction (such as Z-axis direction) and the second direction (such as X-axis direction). FIG. 36B shows a partial top view of the memory device 20 corresponding to the connecting line B-B′ of FIG. 36A, for example corresponding to a planes formed of the second direction (such as X-axis direction) and the third direction (such as Y-axis direction). In the memory device 20, the same referential numerals are used for the elements that are the same as the memory device 10; the similar referential numerals are used for the elements that are similar to the memory device 10. The same or similar elements can be the same or similar materials, and have the same or similar properties, and the repeated contents will not be described in detail.

Referring to FIG. 19, a substrate 110 is provided, and a laminated body S2′ is formed on the upper surface 110a of the substrate 110. The laminated body S2′ includes a first insulating layer 122, a first conductive layer 130, a second insulating layer 124, a sacrificial layer 140, a third insulating layer 126, and a fourth insulating layer 128 sequentially stacked on the upper surface 110a of the substrate 110 along the first direction, for example, by a deposition process. After that, a plurality of first openings 152 are formed, and each of the first openings 152 penetrates the laminated body S1′ and exposes a portion of the substrate 110, but the present invention is not limited thereto. In some embodiments, the first openings 152 may be formed by an etching process, such as a dry etching process. In some embodiments, the substrate 110 may be overetched so that the bottoms of the first openings 152 are lower than the upper surface 110a of the substrate 110.

Referring to FIG. 20, after the first opening 152 is formed, a memory material layer 268′ extending on the laminated body S2 and into the first openings 152 is formed. The memory material layer 268′ is formed, for example, by a deposition process.

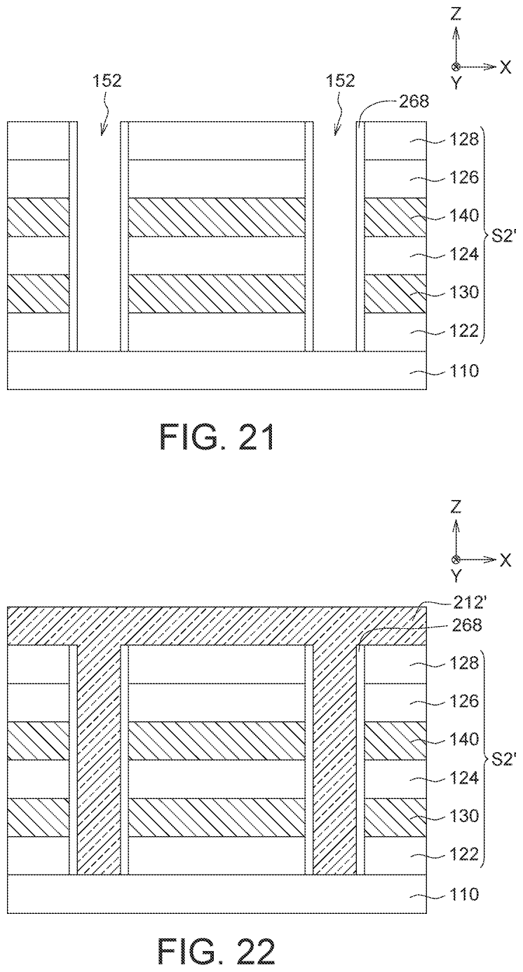

Referring to FIG. 21, the excessive portion of the memory material layer 268′ is removed by an etching process to form the memory layers 268 disposed on the sidewalls of the first openings 152. Each of the memory layers 268 extends along the first direction and penetrates the laminated body S2′, that is, each of the memory layers 268 penetrates the first insulating layer 122, the first conductive layer 130, the second insulating layer 124, the sacrificial layer 140, the third insulating layer 126 and the fourth insulating layer 128. The material of the memory layer 268 is the same or similar to the material of the memory layer 168, and the description will not be repeated here.

Next, referring to FIG. 22, an epitaxial growth layer 212′ covering the memory layer 268, the first opening 152 and the fourth insulating layer 128 is formed by an epitaxial growth process. The epitaxial growth layer 212′ is, for example, an epitaxial growth layer of silicon.

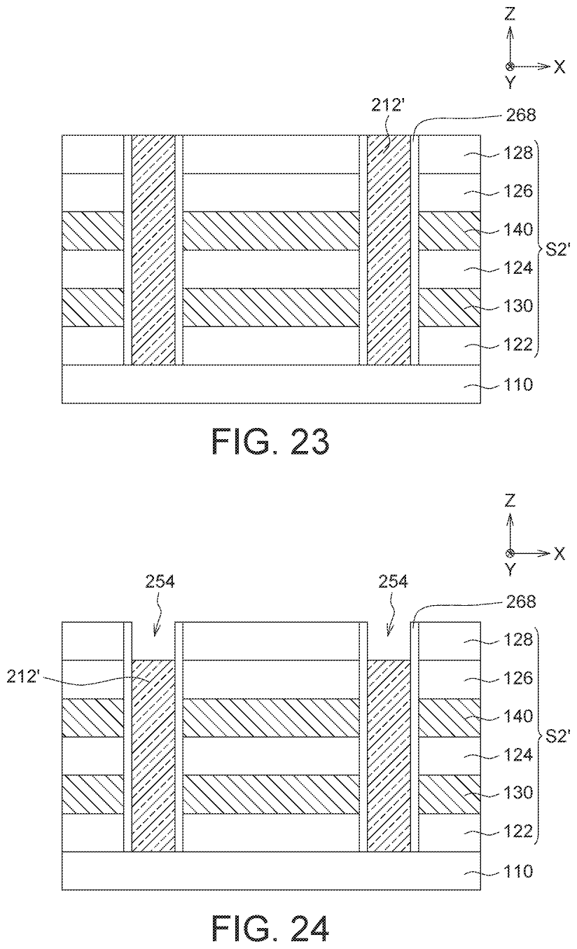

Referring to FIG. 23, the epitaxial growth layer 212′ disposed outside the first openings 152 is removed by a planarization process. The planarization process is, for example, a Chemical-Mechanical Planarization (CMP) process.

Referring to FIG. 24, a portion of the epitaxial growth layer 212′ is removed by an etching process to form a plurality of second openings 254 extending along the first direction. Each of the second openings 254 may be disposed between the memory layer 268 corresponding to the second insulating layer 128 and remaining portions of the epitaxial growth layer 212′. A bottom surface of each of the second openings 254 is, for example, higher than a top surface of the sacrificial layer 140.

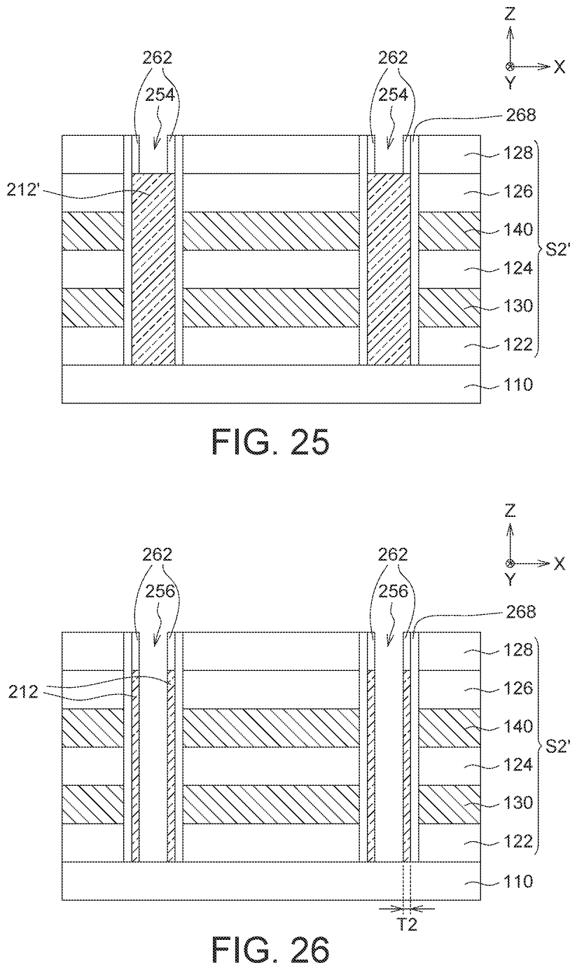

Referring to FIG. 25, an insulating material is filled in the second opening 254 by a deposition process. The insulating material may be oxide or nitride. After that, portions of the insulating material are removed by an etching process to form the spacers 262 on the sidewalls of the second openings 254. The material of the spacer 262 may be oxide, nitride, SiON, BN or TiN or TaN. It can be dielectric or conductor spacer. Dielectric spacer is preferred.

Referring to FIG. 26, a plurality of third openings 256 are formed by an etching process, and the third openings 256 penetrate portions of the epitaxial growth layer 212′. The epitaxial growth layer 212′ disposed on the sidewalls of the first openings 252 are remained, and the substrate 110 is exposed. That is, the epitaxial growth layer 212′ that is not protected by the spacers 262 is removed to form the third openings 256, and a channel layer 212 having a ring shape is formed in the first opening 152. Optionally, if a thickness T1 of the channel layer 212 is to be reduced, an oxidation process can be used to form an oxide on the surface of the channel layer 212. Or, aniso-tropical silicon etching may be used to thin down the channel layer 212. In some embodiments, a thickness T2 of the channel layer 212 may be between 20 Å and 500 Å. In the prefer embodiment, the thickness T2 of the channel layer 212 may be between 20 Å to 200 Å. Compared with the comparative example where the channel layer is solid or columnar in the top view, the channel layer 212 of the present application has a ring shape in the top view (as shown in FIG. 36B), and has a thinner thickness T2, such that the gates (such as a memory gates and a control gate, as detailed below) may have a better control ability.

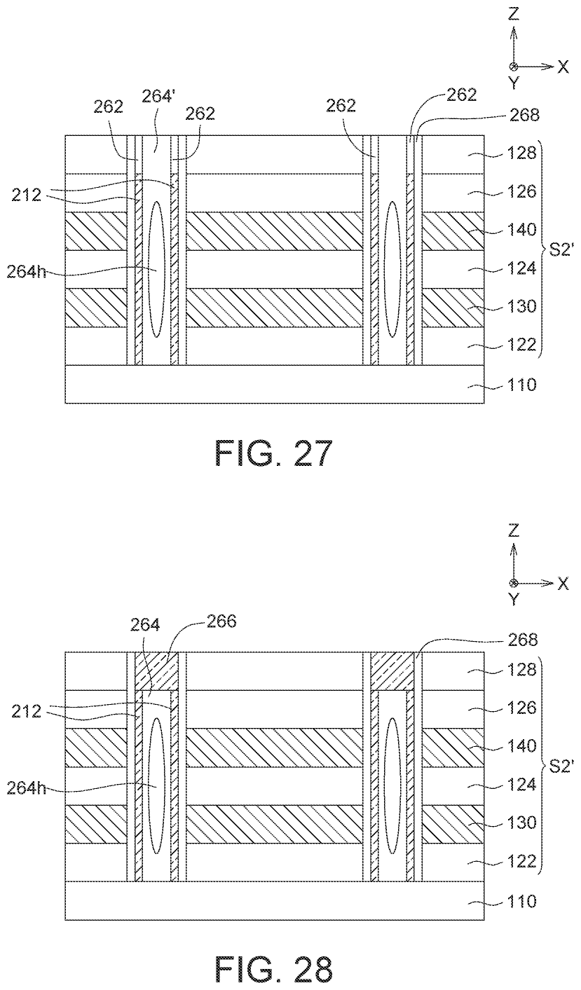

Referring to FIG. 27, after the channel layer 212 is formed, a dielectric material 264′ (such as silicon dioxide, silicon nitride or other suitable dielectric materials) is filled in the third openings 256, and an air gap 264h is formed in the third opening 256. In other embodiments, the dielectric material 264′ may not have an air gap 264h.

Thereafter, referring to FIG. 28, after the spacer 262 and the dielectric material 264′ adjacent to the spacer 262 are etched back, the remaining portion of the dielectric material 264′ forms a dielectric pillar 264, and then a landing pad 266 is formed on the dielectric pillar 264. It is acceptable for spacer 262 to be etched or not etched. The landing pad 266 forms an electrical contact with the channel layer 212. The material of the landing pad 266 is, for example, N⁺ polysilicon or N⁺ polysilicon/salicide. In some embodiments, the spacer 262 may not be etched, and is remained after the landing pad 266 formation. In the present embodiment, the landing pad 266 contacts a top surface of the channel layer 212, but the contact position of the landing pad 266 of the present invention is not limited thereto, once the landing pad 266 is disposed above the sacrificial layer 140 and contacts the channel layer 212, it falls in the scope of the present invention, for example, the landing pad 266 may contact a portion of a side surface of the channel layer 212.

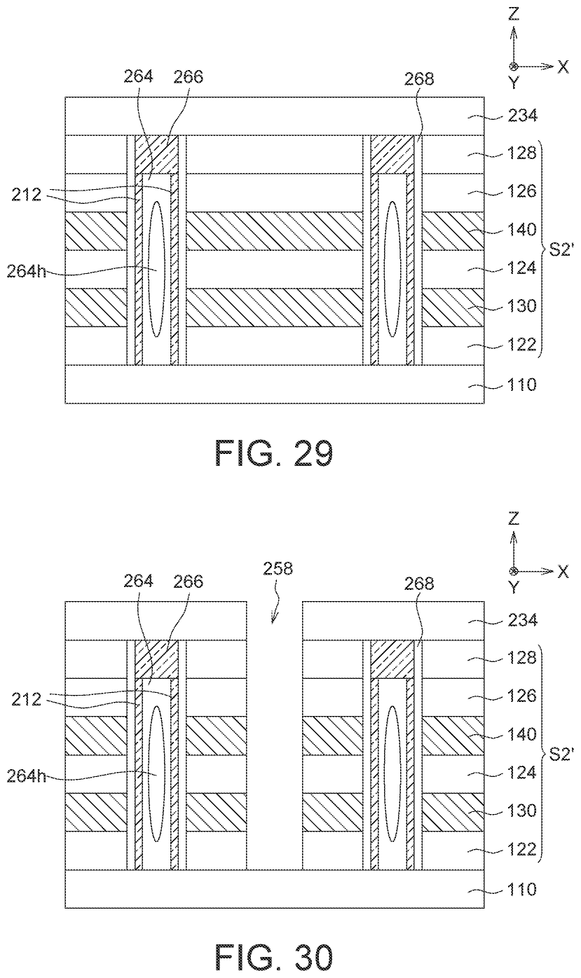

Referring to FIG. 29, after the landing pad 266 is formed, a capping layer 234 is formed to cover the laminated body S2′, the memory layer 268 and the landing pad 266. In one embodiment of the present invention, the capping layer 234 includes oxide.

Referring to FIG. 30, a trench 258 penetrating the laminated body S2′ is formed by an etching process, and the trench 258 may expose a portion of the substrate 110.

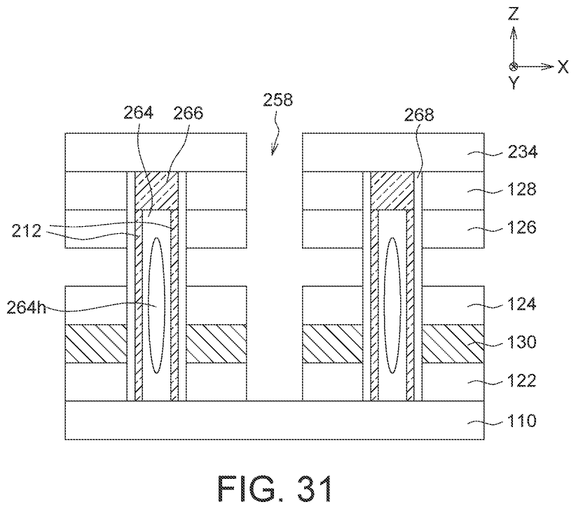

Thereafter, referring to FIG. 31, the sacrificial layer 140 is removed. In the present embodiment, a phosphoric acid (H₃PO₄) solution is used to remove the sacrificial layer 140 through the trench 258.

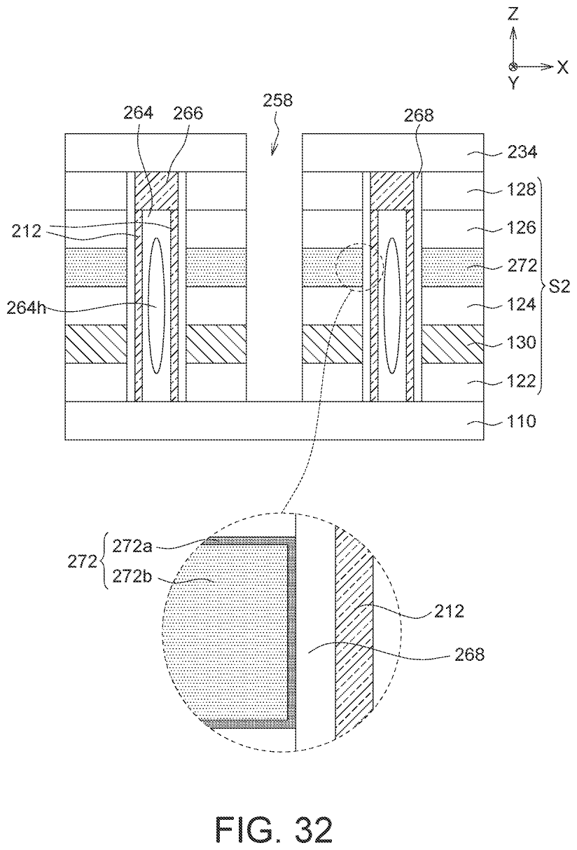

Next, referring to FIG. 32, a second conductive layer 272 is formed at a position where the sacrificial layer 140 is removed. The second conductive layer 272 can be formed by a deposition process.

The second conductive layer 272 may be a multilayer structure. For example, the second conductive layer 272 includes a first conductive structure 272a and a second conductive structure 272b, and the first conductive structure 272a is disposed between the memory layer 268 and the second conductive structure 272b. For example, the material of the first conductive structure 272a may include titanium nitride (TiN), and the material of the second conductive structure 272b may include tungsten (W), but the present invention is not limited thereto. Thereafter, the excessive portion of the second conductive layer 272 is removed by an etching back process to expose the trench 258. Concaves created in the etching process or the etching back process can be filled by depositing an oxide, and then the excess oxide is removed by the etching process.

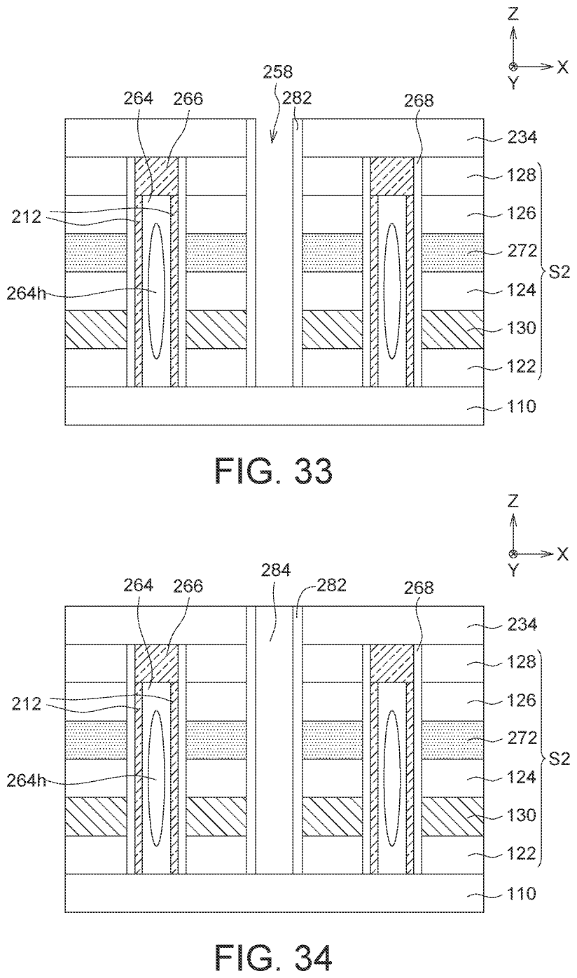

Next, referring to FIG. 33, after filling the trench 258 with an insulating material (such as oxide), a portion of the insulating material is removed to expose a portion of the trench 258 and a portion of the substrate 110, and an isolation structure 282 in the trench 258 is formed. The isolation structure 282 is formed by, for example, a deposition process, and the material of the isolation structure 282 may include an oxide.

Referring to FIG. 34, the trench 258 is filled with conductive material. Then, the excessive portion of the conductive material can be removed by a planarization process (for example, a chemical mechanical planarization process) to form a conductive pillar 284 in electrical contact with the substrate 110. The isolation structure 282 surrounds the conductive pillar 284. The conductive pillar 284 may have a multilayer structure, for example, a double-layer structure. For example, the material of the outer layer of the conductive pillar 284 may include titanium nitride (TiN), and the material of the inner layer of the conductive pillar 284 may include tungsten (W), but the present invention is not limited thereto. The conductive pillar 284 may serve as a source line.

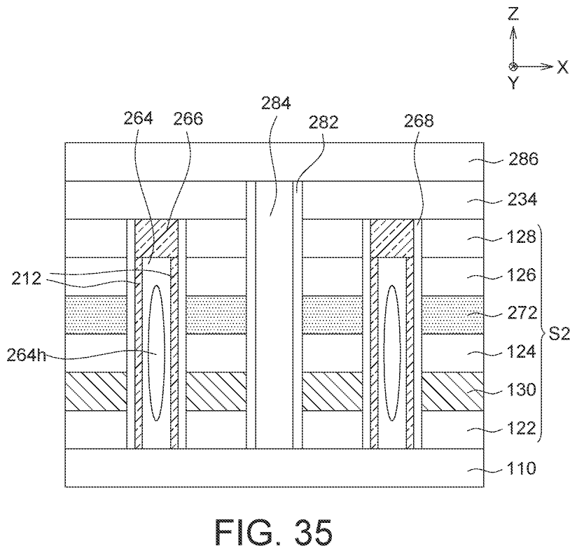

Referring to FIG. 35, a dielectric filling layer 286 is formed on the capping layer 234, the isolation structure 282 and the conductive pillar 284. The material of the dielectric filling layer 286 may include an oxide.

After that, referring to FIGS. 36A and 36B, contact plugs 288 that electrically contacts the landing pads 266 and the conductive pillar 284 are formed. The contact plugs 288 include first plugs 288a and a second plug 288b. The first plugs 288a penetrate a portion of the dielectric filling layer 286 and the capping layer 234 to electrically contact the landing pad 266, and the second plug 288b penetrates a portion of the dielectric filling layer 286 to electrically contact the conductive pillar 284.

According to the above manufacturing steps, the present disclosure provides a memory device 20, as shown in FIGS. 36A and 36B. The memory device 20 includes a substrate 110, a stack S2, a capping layer 234, a dielectric filling layer 286, a memory layer 268, a channel layer 212, a dielectric pillar 264, a landing pad 266, an isolation structure 282, a conductive pillar 284, and a contact plug 288. The stack S2 is disposed on the upper surface 110a of the substrate 110, and the capping layer 234 and the dielectric filling layer 286 are sequentially disposed on the stack S2. The stack S2 includes a first insulating layer 122, a first conductive layer 130, a second insulating layer 124, a second conductive layer 272, a third insulating layer 126 and a fourth insulating layer 128 sequentially stacked on the upper surface 110a of the substrate 110 along the first direction.

In the present embodiment, the second conductive layer 272 may have a multilayer structure, as shown in the enlarged view of FIG. 32. The second conductive layer 272 includes a first conductive structure 272a and a second conductive structure 272b, and the first conductive structure 272a is disposed between the memory layer 268 and the second conductive structure 272b. For example, the material of the first conductive structure 272a may include titanium nitride (TiN), and the material of the second conductive structure 272b may include tungsten (W), but the present invention is not limited thereto.

As shown in FIGS. 36A and 36B, the channel layer 212 and the dielectric pillar 264 penetrate a portion of the stack S1 along the first direction; that is, the channel layer 212 and the dielectric pillar 264 penetrate a portion of the first insulating layer 122, the first conductive layer 130, the second insulating layer 124, the second conductive layer 272 and the third insulating layer 126. The channel layer 212 surrounds the dielectric pillar 264 and is disposed between the dielectric pillar 264 and the memory layer 268. The dielectric pillar 264 may have an air gap 264h. The landing pad 266 may be disposed on the dielectric pillar 264 and the channel layer 212, and the landing pad 266 may be in electrical contact with the channel layer 212. The channel layer 212 may be an epitaxial growth layer, for example, an epitaxial growth layer of silicon. The channel layer 212 has a ring shape and has an inner surface 212s1 and an outer surface 212s2. The inner surface 212s1 is opposite to the outer surface 212s2. The inner surface 212s1 can contact the dielectric pillar 264, and the outer surface 212s2 can contact the memory layer 268. The thickness T2 of the channel layer 212 is defined as the average thickness between the inner surface 212s1 and the outer surface 212s2. In some embodiments, the thickness T2 of the channel layer 212 may be between 20 Å and 500 Å. In the prefer embodiment, the thickness T2 of the channel layer 212 may be between 20 Å to 200 Å. In the present embodiment, the ring shape of the channel layer 212 may be a circle, but the present invention is not limited thereto, the ring shape of the channel layer 212 may be an ellipse, a polygon or the other suitable shape.

Referring to FIG. 36A, the channel layer 212 is directly connected to or in contact with the substrate 110 disposed below the channel layer 212.

FIG. 36C show a cross-sectional view of a memory device 20′ according to a further embodiment of the present disclosure. In the memory device 20′, the same referential numerals are used for the elements that are the same as the memory device 20; the similar referential numerals are used for the elements that are similar to the memory device 20. The same or similar elements can be the same or similar materials, and have the same or similar properties, and the repeated contents will not be described in detail.

Referring to FIG. 36C, the difference between the memory devices 20 and 20′ is in that the memory device 20′ further comprises a lower remnant portion 213 disposed below the channel layer 212″ and the dielectric pillar 264″. That is, the channel layer 212″ is not directly connected to or in contact with the substrate 110 disposed below the channel layer 212″. The lower remnant portion 213 is disposed between the channel layer 212″ and the substrate 110. The lower remnant portion 213 is directly connected to the channel layer 212″ and the substrate 110. The material of the channel layer 212″ may be the same as the material of the lower remnant portion 213 (such as polysilicon), and the channel layer 212″ and the lower remnant portion 213 may be connected in a borderless way (i.e. the channel layer 212″ and the lower remnant portion 213 may be an integral structure). A top surface 213s of the lower remnant portion 213 may concave downwardly along the first direction (i.e. Z-axis direction).

Compared with the comparative example where the channel layer is solid or columnar in the top view (the size of the first opening used to form the channel layer being the same as the size of the first opening 152 of the present application), the channel layer 212 of the present application has a ring shape in the top view (such as FIG. 36B) and has a thinner thickness T2, such that the Subthreshold Swing (SS) may be decreased, and the random telegraph noise may be reduced, and the programming/erasing window (P/E window) can be larger. That is, the gates can have a better control ability, and it is more advantageous for operating the memory, for example, the memory having a Multi-Level Cell (MLC) or a Triple-Level Cell (TLC).

In the present embodiment, the memory layer 268 extends along the first direction penetrating the stack S2 (that is, penetrating the first insulating layer 122, the first conductive layer 130, the second insulating layer 124, the second conductive layer 272, the third insulating layer 126 and the fourth insulating layer 128). The memory layer 268 is disposed between the first insulating layer 122 and the channel layer 112, between the first conductive layer 130 and the channel layer 212, between the second insulating layer 124 and the channel layer 212, and the second conductive layer 272 and the channel layer 212, between the third insulating layer 126 and the channel layer 212, and between the fourth insulating layer 128 and the landing pad 266. The memory layer 268 surrounds the channel layer 212 and the landing pad 266. The material of the memory layer 268 may be the same as the material of the memory layer 168, and the description will not be repeated here.

According to an embodiment, the isolation structure 282 and the conductive pillar 284 penetrate the capping layer 234 and the stack S2 along the first direction, and the isolation structure 282 surrounds the conductive pillar 284. The contact plugs 188 electrically contact the landing pads 266 and the conductive pillar 284. The contact plugs 288 include first plugs 288a and a second plug 288b. The first plugs 288a penetrate a portion of the dielectric filling layer 286 and the capping layer 234 to electrically contact the landing pad 266, and the second plug 288b penetrates a portion of the dielectric filling layer 286 to electrically contact the conductive pillar 284. The material of the contact plugs 288 includes a conductive material, such as tungsten or other suitable conductive materials.

In some embodiments, the conductive pillar 284 can be used as a source line; the first conductive layer 130 can be used as a control gate; and the second conductive layer 272 can be used as a memory gate.

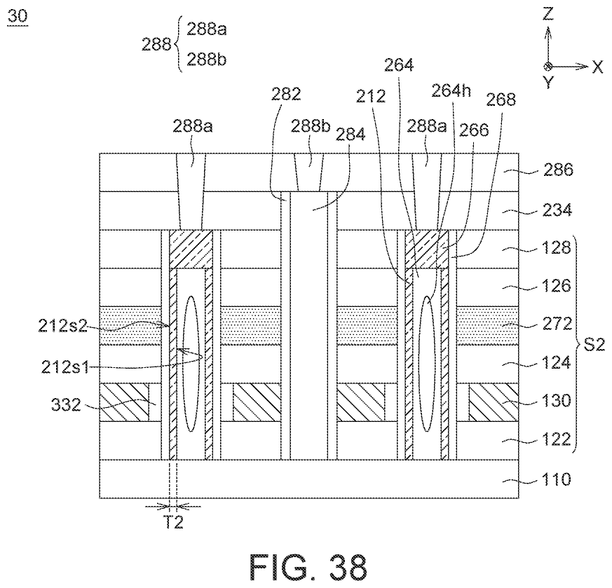

FIGS. 37 to 38 show cross-sectional views of a method for fabricating the memory device 30 according to an embodiment of the disclosure, for example, corresponding to a plane formed by the first direction (such as Z-axis direction) and the second direction (such as X-axis direction).

After the process steps shown in FIG. 19 and related paragraphs are performed, oxide layers 332 are formed on the side surfaces of the first conductive layer 130 exposed from the first openings 152 by an oxidation process, and oxide layers (not shown) are formed on the surface of the substrate 110 exposed from the first openings 152. Thereafter, the oxide layers formed on the surface of the substrate 110 are removed by an etching process, and the oxide layer 332 is remained, as shown in FIG. 37. If the materials of the first insulating layer 122, the second insulating layer 124, the third insulating layer 126, and the fourth insulating layer 128 include oxides, the purity of the oxides of the first insulating layer 122, the second insulating layer 124, the third insulating layer 126 and the fourth insulating layer 128 is less than the purity of the oxides of the oxide layers 332 formed by the oxidation process.

Next, the steps shown in FIGS. 20 to 35 and related paragraphs are proceeded. Thereafter, referring to FIG. 38, contact plugs 288 electrically contacting the landing pads 266 and the conductive pillar 284 are formed. The contact plugs 288 include first plugs 288a and a second plug 288b. The first plugs 288a penetrate a portion of the dielectric filling layer 286 and the capping layer 234 to electrically contact the landing pads 266, and the second plug 288b penetrates a portion of the dielectric filling layer 286 to electrically contact the conductive pillar 284.

According to the above manufacturing steps, the present disclosure provides a memory device 30, as shown in FIG. 38. The memory device 30 includes a substrate 110, a stack S2, a capping layer 234, a dielectric filling layer 286, oxide layers 332, memory layers 268, channel layers 212, a dielectric pillar 264, landing pads 266, an isolation structure 282, a conductive pillar 284, and contact plugs 288. The structure of the memory device 30 is similar to the structure of the memory device 20; the difference therebetween is that the memory device 30 further includes oxide layers 322. The same elements have the same properties, and the repeated portion will not be described in detail.

In an embodiment, the oxide layer 332 may surround a portion of the memory layer 268 and the channel layer 212. For example, the oxide layer 332 is disposed between the first conductive layer 130 and the memory layer 268.

The present disclosure provides a memory device and a method for fabricating the same. The memory device includes a substrate, a stack, a channel layer, and a memory layer. The substrate has an upper surface. The stack is disposed on a substrate, wherein the stack includes a first insulating layer, a first conductive layer, a second insulating layer, a second conductive layer, and a third insulating layer sequentially stacked on the upper surface of the substrate along a first direction. The channel layer penetrates the stack along the first direction, wherein the channel layer has a ring shape in a top view. The memory layer is disposed between the channel layer and the second conductive layer.

Compared with the two-dimensional NOR memory device, the three-dimensional NOR memory device of the present application has a higher storage capacity, and the required area of the memory device can be reduced. Furthermore, compared to the comparative example where the channel layer is solid or columnar in the top view, the channel layer of the present application has a ring shape in the top view and has a thinner thickness, such that the Subthreshold Swing (SS) may be decreased, and the random telegraph noise may be reduced; the programming/erasing window (P/E window) can be larger. That is, the gate may have a better control ability, and it is more advantageous for operating the memory.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory device, comprising:
a substrate having an upper surface;
a stack disposed on the substrate, wherein the stack comprises a first insulating layer, a first conductive layer, a second insulating layer, a second conductive layer and a third insulating layer sequentially stacked on the upper surface of the substrate along a first direction;
a channel layer penetrating the stack along the first direction, wherein the channel layer has a ring shape along a cross section view in a plane perpendicular to the first direction; and
a memory layer disposed between the channel layer and the second conductive layer.

2. The memory device according to claim 1, further comprising a dielectric pillar, wherein the dielectric pillar penetrates the stack, and the channel layer surrounds the dielectric pillar.

3. The memory device according to claim 2, wherein the channel layer is disposed between the dielectric pillar and the memory layer.

4. The memory device according to claim 2, wherein the channel layer has an inner surface and an outer surface, the inner surface is opposite to the outer surface, and the inner surface contacts the dielectric pillar, and the outer surface contacts the memory layer.

5. The memory device according to claim 1, wherein the channel layer is directly connected to the substrate.

6. The memory device according to claim 1, further comprising a lower remnant portion disposed below the channel layer.

7. The memory device according to claim 1, wherein a portion of the memory layer extends along the first direction and is disposed between the second conductive layer and the channel layer; other portions of the memory layer extend along a second direction and is disposed between the second conductive layer and the second insulating layer and between the second conductive layer and the third insulating layer, wherein the first direction and the second direction are intersected.

8. The memory device according to claim 1, wherein the memory layer extends along the first direction and penetrates the first insulating layer, the first conductive layer, the second insulating layer, the second conductive layer and the third insulating layer.

9. The memory device according to claim 1, further comprising an oxide layer disposed between the first conductive layer and the channel layer.

10. The memory device according to claim 1, further comprising an oxide layer disposed between the first conductive layer and the memory layer.

11. A method for fabricating a memory device, comprising:
providing a substrate, wherein the substrate has an upper surface;
forming a laminated body on the substrate, wherein the laminated body comprises a first insulating layer, a first conductive layer, a second insulating layer, a sacrificial layer and a third insulating layer along a first direction;
forming a first opening penetrating the laminated body;
forming a channel layer in the first opening, wherein the channel layer has a ring shape along a cross section view in a plane perpendicular to the first direction;
removing the sacrificial layer;
forming a second conductive layer at a position where the sacrificial layer is removed; and
forming a memory layer disposed between the channel layer and the second conductive layer.

12. The method for fabricating the memory device according to claim 11, wherein the step of forming the channel layer further comprises:
forming an epitaxial growth layer covering the first opening by an epitaxial growth process;
removing a portion of the epitaxial growth layer to form a second opening, wherein a bottom surface of the second opening is higher than a top surface of the sacrificial layer;
forming a spacer on a sidewall of the second opening; and
removing the epitaxial growth layer not protected by the spacer to form a third opening exposing the substrate, and form the channel layer.

13. The method for fabricating the memory device according to claim 12, further comprising:
filling the third opening with a dielectric material; and
etching back the spacer and the dielectric material adjacent to the spacer, and a remaining portion of the dielectric material forming a dielectric pillar, wherein the channel layer surrounds the dielectric pillar.

14. The method for fabricating the memory device according to claim 13, further comprising:
forming a trench penetrating the laminated body, the trench exposing a portion of the substrate;
removing the sacrificial layer through the trench; and
sequentially forming the memory layer and the second conductive layer at the position where the sacrificial layer is removed.

15. The method for fabricating the memory device according to claim 14, wherein a portion of the memory layer extends along the first direction and is disposed between the second conductive layer and the channel layer; other portions of the memory layer extend along a second direction and are disposed between the second conductive layer and the second insulating layer and between the second conductive layer and the third insulating layer, wherein the first direction and the second direction are intersected.

16. The method for fabricating the memory device according to claim 13, further comprising:
forming a memory material layer extending on the laminated body and into the first opening after forming the first opening; and
removing an excessive portion of the memory material layer to form the memory layer disposed on a sidewall of the first opening.

17. The method for fabricating the memory device according to claim 16, wherein the memory layer extends along the first direction and penetrates the first insulating layer, the first conductive layer, the second insulating layer, the second conductive layer and the third insulating layer.

18. The method for fabricating the memory device according to claim 13, wherein the channel layer is disposed between the dielectric pillar and the memory layer.

19. The method for fabricating the memory device according to claim 13, wherein the channel layer has an inner surface and an outer surface, the inner surface is opposite to the outer surface, wherein the inner surface contacts the dielectric pillar, and the outer surface contacts the memory layer.

20. The method for fabricating the memory device according to claim 11 further comprising:
forming an oxide layer on a side surface of the first conductive layer exposed from the first opening through an oxidation process.
